(19) United States
(12) Patent Application Publication
(10) Pub. No.: US 2002/0028547 A1
(43) Pub. Date: Mar. 7, 2002

(54) Flash memory programming method

(75) Inventors: Won-il Ryu, Yongin-city (KR); Byung-ki Kim, Yongin-city (KR); Ji-ho Kim, Yongin-city (KR); Seong-kyun Kim, Yongin-city (KR)

Correspondence Address: The Law Offices of Eugene M Lee, PLLC, 2111 Wilson Boulevard, Suite 1200, Arlington, VA, 22201, US

(73) Assignee: Samsung Electronics Co., Ltd

(21) Appl. No.: 09/866,916

(22) Filed: May 30, 2001

(30) Foreign Application Priority Data
May 30, 2000 (KR) 00-29300

(51) Int. Cl. H01L 21/8238

(52) U.S. Cl. 438/200

(57) ABSTRACT

A method of programming a flash memory module, wherein a plurality of flash memory cells are arrayed in a substrate; each memory cell having a source, a drain, a floating gate, and a control gate, which are separated from one another on the substrate, an insulating layer formed on the substrate between the source and drain, and also separating the source/drain and control gate, and a floating gate wherein a detrapping process with appropriate bias conditions is applied either after an erase step for erasing data written to the flash memory cell or after a write step for writing predetermined data, in order to remove electrons trapped in the insulating layer excluding the floating gate. During the detrapping process, electrons trapped in a region excluding a floating gate are removed, thereby suppressing degradation caused by repeated write/erase operations.

### BACKGROUND OF THE INVENTION

1. Field of the Invention

The present invention relates to a flash memory programming method. More particularly, the present invention relates to a method of programming a flash memory which is capable of suppressing degradation caused by repeated erase/write operations.

2. Description of the Related Art

Flash electrically erasable and programmable read only memories (EEPROMs) which provide electrical writing and erasing capability are of various types depending on the cell structure thereof. EEPROMs are largely classified into stack gate type and split gate type, of which the stack gate type is also known as industrial-standard type. Programming for writing data to a memory module including an array of a plurality of memory cells consists of an erase operation for erasing previously recorded data and a write operation for writing new data.

FIG. 1 illustrates a cross sectional view showing the cell structure of a general stack gate type EEPROM. Referring to FIG. 1, a flash memory includes a substrate 10, source 11, drain 12, control gate 13, and floating gate 14. The stack gate type flash memory has a structure similar to a typical metal-oxide-semiconductor (MOS) device further including the floating gate 14 underlying the control gate 13, the portions of which overlap the source 11 and the drain 12. The floating gate 14 has a structure which is electrically insulated and isolated from the source 11, drain 12, and control gate 13. The flash memory records binary information by electron injection into (write)/electron discharge from (erase) the floating gate 14. The electron injection into the floating gate 14 is performed by channel hot electron injection (CHEI) mechanism that uses a hot electron in a channel 16 between the source 11 and drain 12. The electron discharge from the floating gate 14 is carried out by using one of various biasing methods. The most general one is to induce Fowler-Nordheim (F-N) tunneling of electrons from the floating gate 14 into the source 11 through an insulating layer 15 by applying a high electric field.

FIG. 2 shows the structure of a split gate type flash memory cell in which a floating gate is slanted toward a source. An electron injection into a floating gate 24 of the memory cell, as shown in FIG. 2, is accomplished by CHEI using a hot electron in a channel 26 between a source 21 and a drain 22 in a substrate 20. Furthermore, for electron injection, the split gate type flash memory cell utilizes a bias approach in which a high electric field produces F-N tunneling of electrons from a source 21 into the floating gate 24 through the channel 26 and an insulating layer 25. In addition, in order to drive electrons out of the floating gate 24, the split gate type flash memory cell utilizes F-N tunneling of electrons out of the floating gate 24 into a control gate 23 through the insulting layer 25, induced by a high electric field. The flash memory which injects and discharges electrons in this way is subjected to degradation as the number of erase/write cycles increases.

In connection therewith, FIG. 3 shows the result of measuring the change in the threshold voltage Vth of a stack gate type flash memory cell with respect to the number of erase/write cycles. As shown in FIG. 3, the flash memory, in which an erase operation by F-N tunneling and a write operation by CHEI are performed, suffers from significant degradation in endurance if the number of erase/write cycles exceeds 10³. The degradation characteristic is true of a split gate type flash memory.

The main cause of degradation in a flash memory which performs a write operation by CHEI and an erase operation by F-N tunneling is known to be the trapping of electrons in the insulating layers 15 and 25 during an F-N tunneling process when an erase operation is performed. Based on the fact that the degradation is caused by electrons trapped in the insulating layers 15 and 25 during electron discharge, various schemes have been so far directed toward improving the quality of the insulating layers 15 and 25 for suppressing damage thereof during electron discharge, and improving the channel structure for enhanced tunneling efficiency.

### SUMMARY OF THE INVENTION

To solve the above problems, it is a feature of an embodiment of the present invention to provide a flash memory programming method which suppresses degradation caused by repeated erase/write cycles to increase the endurance of a flash memory.

Accordingly, an embodiment of the present invention provides a method of programming a flash memory module. In this method of programming a flash memory module in which a plurality of flash memory cells are arrayed in a substrate; each memory cell having a source, a drain, a floating gate, and a control gate, which are separated from one another on the substrate, an insulating layer formed on the substrate between the source and drain, and also separating the source/drain and control gate, and a floating gate wherein a detrapping process with appropriate bias conditions is applied either after an erase step for erasing data written to the flash memory cell or after a write step for writing predetermined data, in order to remove electrons trapped on the insulating layer excluding the floating gate. During the detrapping process, electrons trapped in a region excluding a floating gate are removed, thereby suppressing degradation caused by repeated write/erase operations.

Preferably, in the detrapping process, a predetermined bias voltage is applied to the source in such a way that the electric potential of the source is maintained higher than the electric potential of the floating gate. In the detrapping process, a predetermined bias voltage may be applied to the substrate in such a way that the electric potential of the substrate is maintained higher than the electric potential of the floating gate. In the detrapping process, a predetermined bias voltage may be applied to the drain in such a way that the electric potential of the drain is maintained higher than the electric potential of the floating gate.

Furthermore, when a predetermined number of flash memory cells are coupled on a block-by-block basis so that the memory cells may share the control gate and source, and the write operation is performed on the flash memory cells within the block on a bit-by-bit basis at predetermined intervals, the detrapping process may be performed on all the flash memory cells within the block between each interval of the write operation which is made on a bit-by-bit basis. When the write operation is performed on the flash memory cells within the block on a byte-by-byte basis at predetermined intervals, the detrapping process may be performed on all the flash memory cells within the block between each interval of the write operation which is made on a byte-by-byte basis. After the write operation is performed by a block-by-block basis, the detrapping process may be performed on all the flash memory cells within the block.

An embodiment of the present invention also provides a method of programming a flash memory module in which a plurality of flash memory cells are arrayed, each memory cell including a substrate, a source, a drain and a control gate which are separated from one another on the substrate, an insulating layer formed between the source and drain, a control gate, and a floating gate overlying the insulating layer, the method comprising: (a) performing an erase operation for applying bias conditions established for erasing data written to the flash memory cell; and (b) performing a detrapping process for applying bias conditions established for removing electrons trapped on the insulating layer excluding the floating gate, following the erase operation.

These and other features of the present invention will be readily apparent to those of ordinary skill in the art upon review of the detailed description that follows.

### BRIEF DESCRIPTION OF THE DRAWINGS

The above features and advantages of the present invention will become more apparent by describing in detail a preferred embodiment thereof with reference to the attached drawings in which:

FIG. 1 illustrates a cross-sectional view showing the structure of a general stack gate type flash memory cell according to the prior art;

FIG. 2 illustrates a cross-sectional view showing the structure of a general split gate type flash memory cell according to the prior art;

FIG. 3 illustrates a graph showing a change in a threshold voltage in a stack gate type flash memory with respect to the number of erase/write cycles according to a conventional programming method;

FIG. 4 illustrates an electrode arrangement structure for a simulation experiment to determine a characteristic change of a general split gate type memory cell according to a programming method of the present invention;

FIG. 5 illustrates a graph showing the recovered characteristic of drain current in a split gate type memory cell by addition of a detrap step according to an embodiment of the present invention;

FIG. 6 illustrates the structure of a split gate type memory cell array;

FIG. 7 illustrates a waveform diagram showing bias conditions in a memory module in each step of a programming operation according to an embodiment of the present invention;

FIG. 8 illustrates a graph showing change in drain current with respect to the number of erase/write cycles under the bias conditions shown in FIG. 7, when a detrap step is not performed according to the conventional programming method;

FIG. 9 illustrates a graph showing change in drain current with respect to the number of erase/write cycles under the bias conditions shown in FIG. 7, when a detrap step is repeatedly performed according to an embodiment of the present invention;

FIG. 10 illustrates bias conditions in a stack gate type memory cell according to an embodiment of the present invention;

FIG. 11 illustrates a waveform diagram showing bias conditions in a memory module including an array of cells like that shown in FIG. 10 in each step of a programming operation according to an embodiment of the present invention;

FIG. 12 illustrates a graph showing change in drain current with respect to the number of erase/write cycles under the bias conditions shown in FIG. 11, when a detrap step is not performed according to the conventional programming method; and

FIG. 13 illustrates a graph showing change in drain current with respect to the number of erase/write cycles under the bias conditions shown in FIG. 7, when a detrap step is repeatedly performed according to an embodiment of the present invention.

### DETAILED DESCRIPTION OF PREFERRED EMBODIMENTS

Korean Patent Application No. 00-29300, filed on May 30, 2000, and entitled: “Flash Memory Programming Method,” is incorporated by reference herein in its entirety.

The present invention now will be described more fully with reference to the accompanying drawings, in which preferred embodiments of the invention are shown. This invention may, however, be embodied in many different forms and should not be construed as being limited to the embodiments set forth herein; rather, these embodiments are provided so that this disclosure will be thorough and complete, and will fully convey the concept of the invention to those of ordinary skilled in the art. In the drawings, the thicknesses of layers and regions are exaggerated for clarity. It will also be understood that when a layer is referred to as being “on” another layer or substrate, it can be directly on the other layer or substrate, and one or more intervening layers may also be present. Further, it will be understood that when a layer is referred to as being “under” another layer, it can be directly under, and one or more intervening layers may also be present.

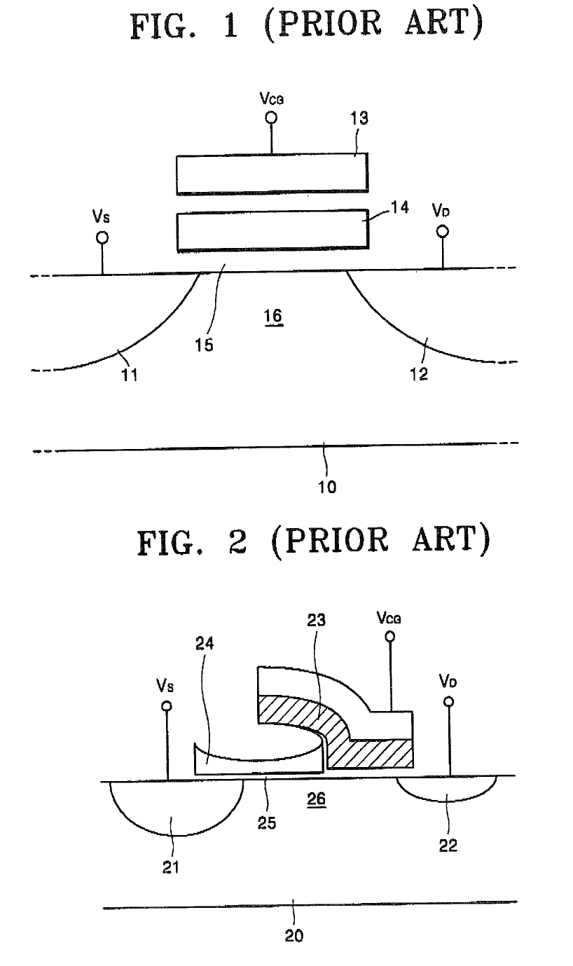

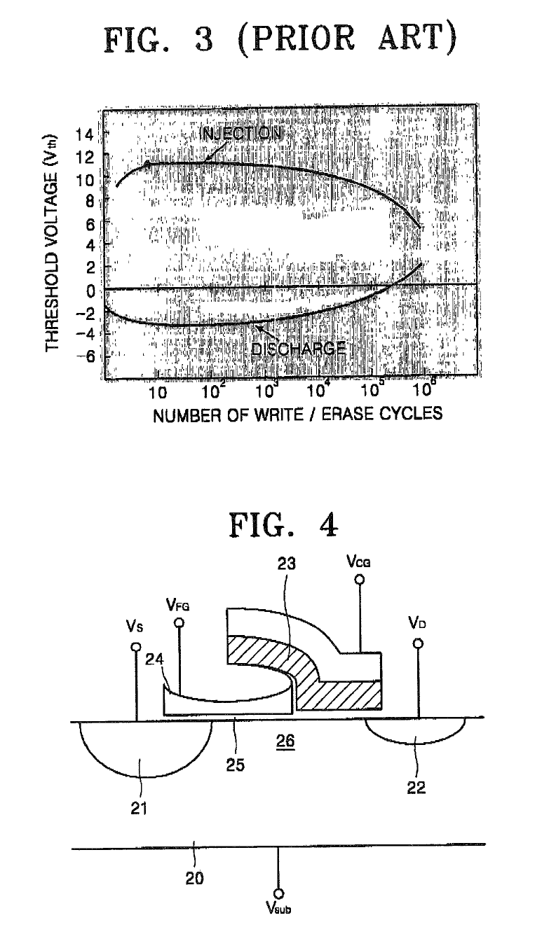

A method of programming a flash memory module according to an embodiment the present invention involves performing an erase and/or write step followed by a detrap step. That is to say, the programming method according to an embodiment of the present invention is characterized by including a detrapping process for removing electrons trapped in the insulating layers 15 and 25 (see reference characters in FIGS. 1 and 2), which cause degradation, during the erase operation or write operation, after performing the erase operation and/or write operation. A detrap process, which is additionally performed on a memory cell after a write operation, will now be described.

In order to write data to a memory cell via electron injection during a write operation, a bias voltage is applied by a CHEI technique so that electrons may be injected into floating gates 14 and 24 within a memory cell. In a detrapping process, a bias voltage is applied for removing electrons that are trapped in the insulating layers 15 and 25 during the write operation. The bias voltage applied during the detrapping process is determined in such a way as to remove electrons trapped in a region other than the floating gates 14 and 24 while retaining electrons trapped in the floating gates 14 and 24 during a write step.

As an example of bias voltage conditions applied in a detrapping process, a predetermined bias voltage is applied to any one of sources 11 and 21, drains 12 and 22, and substrates 10 and 20. Alternatively, a predetermined bias voltage is applied to at least two of the sources 11 and 21, drains 12 and 22, and substrates 10 and 20.

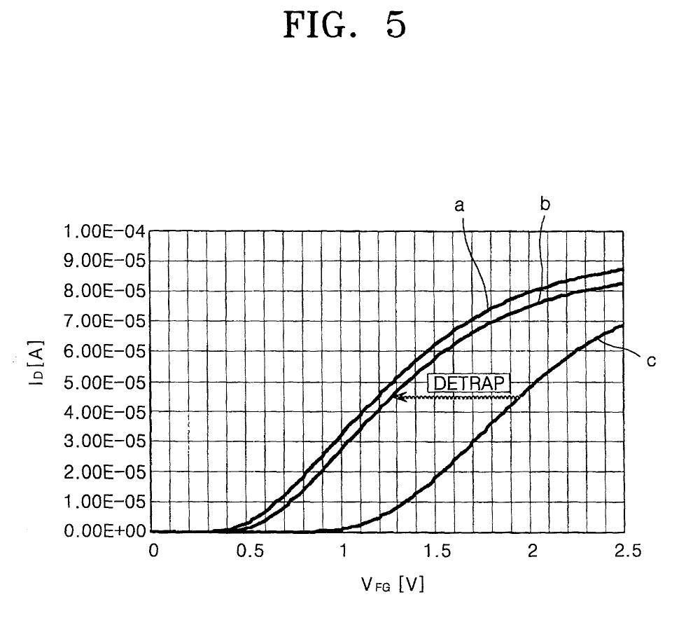

FIG. 4 illustrates bias electrodes for a test to examine change in the characteristics of a split gate type flash memory cell with respect to repetition of erase/write operations, when a detrapping process is added according to an embodiment of the present invention. In a real cell, the floating gate 24 is in isolation, and thus a bias voltage cannot be applied directly from the outside. Furthermore, a channel hot electron injection (CHEI) mechanism has a self-limiting characteristic in which electron injection ceases to occur if the number of electrons on the floating gate 24 reaches a certain amount. However, if a electrode VFG embedded for testing is utilized so that a voltage can be applied to the floating gate 24 directly from the outside, CHEI continuously occurs while a bias voltage is applied in a write operation, thereby obtaining the same substitution effect as the change of characteristics that occur in a real cell.

The following Table 1 shows the bias voltage applied to each terminal of FIG. 4 for examining degradation.

TABLE 1

| | Write bias | Detrap bias |
|---|---|---|
| Vₛ | 11 V | 11 V |
| V_{D} | 0 V | 5 V |
| V_{CG} | 1.5 V | 0 V |
| V_{FG} | 7 V | 0 V |
| V_{SUB} | 0 V | 11 V |

In Table 1, V_{S}, V_{D}, V_{CG}, V_{FG}, and V_{SUB} each denote voltages applied to the source 21, drain 22, control gate 23, floating gate 24, and substrate 20. FIG. 5 illustrates the results of measuring drain current while a bias voltage was applied for three minutes during a write operation and during a detrap process, respectively. Reference characters a, b, and c in FIG. 5 are curves for drain current measured in an initial state, in a detrap state, and in a write state, respectively. As shown in FIG. 5, after a write operation, a split gate type memory cell showed degradation in which a drain current I_{D} was considerably reduced compared with a drain current in an initial state. However, when the following detrapping process was performed, the drain current was restored close to its initial state. The result of the simulation experiment demonstrated that if a write operation was performed by addition of a detrapping process according to an embodiment of the present invention, a characteristic of a cell was restored by actively removing electrons trapped on the insulating layers 15 and 25.

By considering the existing write method, the conditions of a bias applied during a detrapping process may be appropriately established. In other words, the bias conditions in a detrapping process may be appropriately selected depending upon the type, structure and operation conditions of a flash memory cell. Furthermore, in a flash memory module in which a plurality of cells are arrayed, if a partial write is performed to a predetermined number of cells at predetermined intervals, a partial write operation and a detrapping process may be repeatedly performed. In other words, a partial write operation is performed in units of a bit, byte, or block including cells which share a word line, followed by a detrapping process. Alternatively, a detrapping process may be added whenever an erase/write cycle for the overall memory module comes to a predetermined number of cycles.

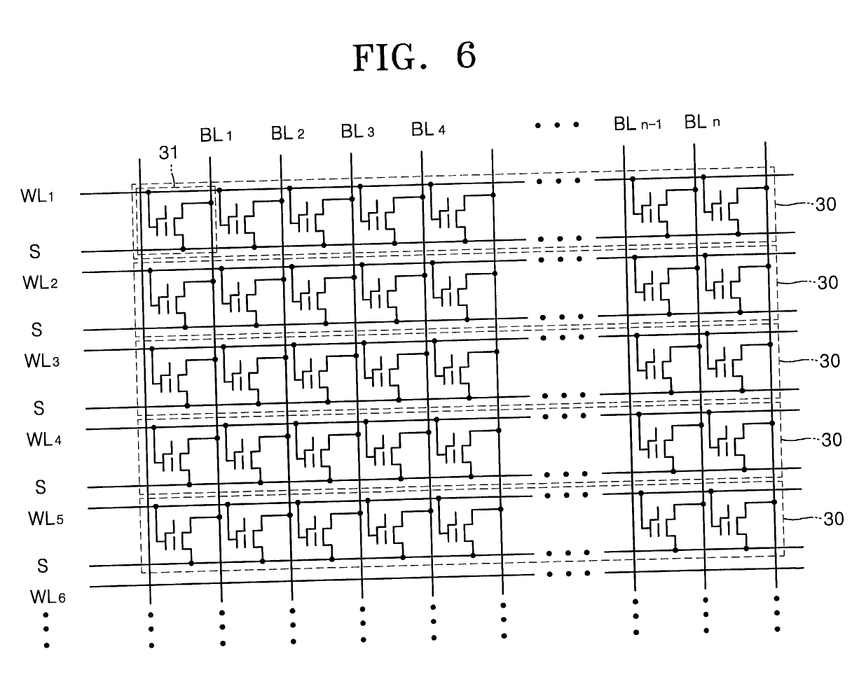

As an example, split gate type flash memory cells having an array structure as illustrated in FIG. 6 will now be described. Referring to FIG. 6, a plurality of memory cells 31 within a unit block 30 are coupled in such a way as to share a word line WL and a source line S. Furthermore, the memory cell 31 of each unit block 30 is coupled in such a way as to share a bit line BL with other memory cells along a direction perpendicular to the word line WL. Here, the word line WL is a line which control gates of the memory cells 31 within a unit block share with each other, the source line S is a line which sources of the memory cells 31 within a unit block share with each other, and the bit line BL is a line which drains of the memory cells 31 in a direction perpendicular to the word line share with each other.

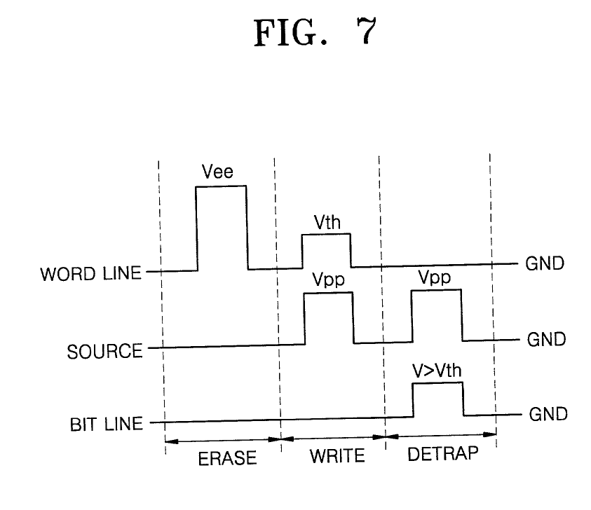

As shown in FIG. 7, in a programming method according to an embodiment of the present invention, a bias voltage was applied to the memory module having the above structure in each step. In FIG. 7, Vₑₑ, Vₜₕ, Vₚₚ are 14 V, 1.5 V, and 11 V, respectively. Furthermore, after erasing data from individual blocks 30 including the cells 31 that share a word line, a partial write operation was performed on a byte-by-byte basis within the unit block 30, followed by a detrapping process between each partial write operation. During a detrapping process, a voltage Vₚₚ is applied to a cell source 21 to remove electrons trapped in the insulating layer 25 through the source 21. A voltage, which is a little higher than a threshold voltage Vₜₕ, was applied to the bit line BL in order to prevent undesired CHEI or electron injection by cutting off the movement of electrons from the drain 22 to the source 21.

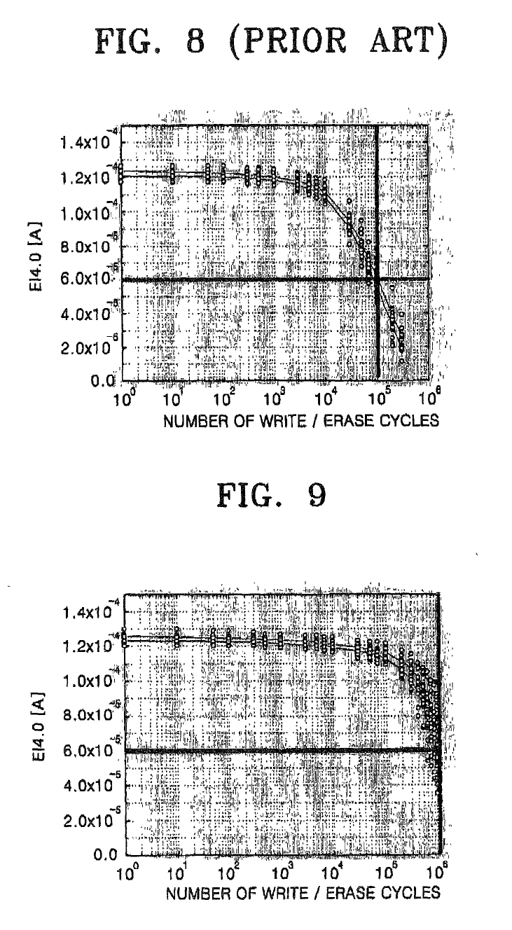

FIG. 8 illustrates degradation under the above bias conditions according to a conventional erase/write repetition, from which a detrapping process is excluded. FIG. 9 illustrates degradation according to erase/write/detrap repetition according to an embodiment of the present invention. If the endurance is defined by the number of erase/write cycles performed until drain current is reduced to half of the drain current in an initial state, as erase/write operations are repeated, endurance is about 10⁵ in the conventional art, and about 10⁶ in the present invention. Thus, according to a programming method having a detrapping process according to an embodiment of the present invention, endurance is improved by a factor of about ten as compared to the conventional art.

In the case in which a detrapping process is added between erase and write operations according to another embodiment of the present invention, the bias conditions in a detrapping process described through FIG. 7 are applied in the same manner.

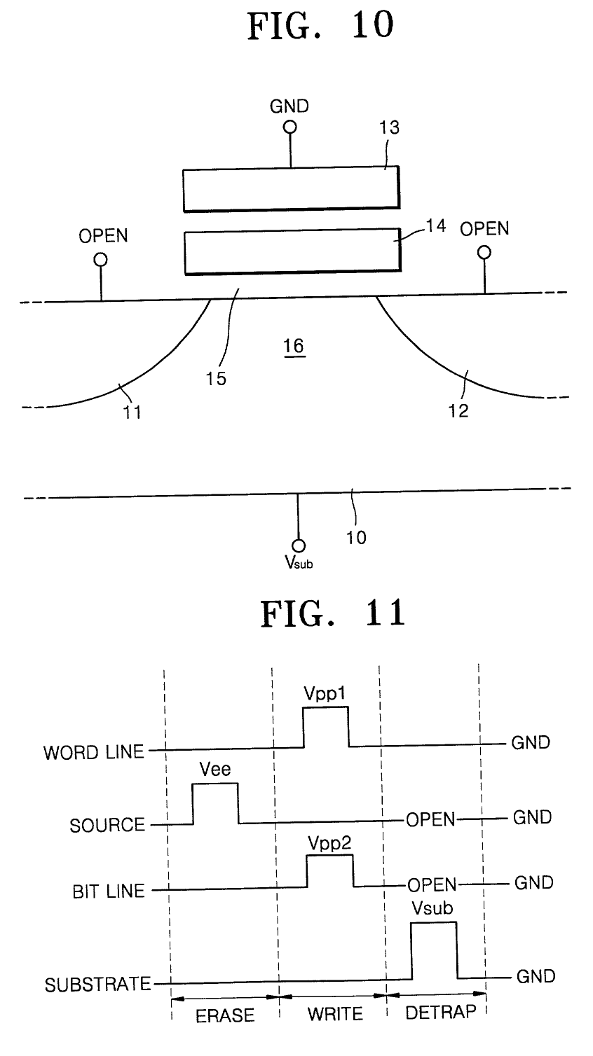

Meanwhile, a stack gate type flash memory provides low electron injection efficiency by CHEI compared with a split gate type flash memory, so that a write step is usually performed on a bit-by-bit basis. An example of bias conditions for the stack gate flash memory in a detrapping process is shown in FIG. 10. More specifically, in a detrapping process, in order to remove electrons trapped on an insulating layer 15, a predetermined positive potential V_{SUB} is applied to a substrate 10, a source 11 and a drain 12 are maintained open, and a control gate 13 is grounded. Here, the potential V_{SUB} applied to the substrate 10 is set within the range of not leaking electrons trapped on a floating gate 14.

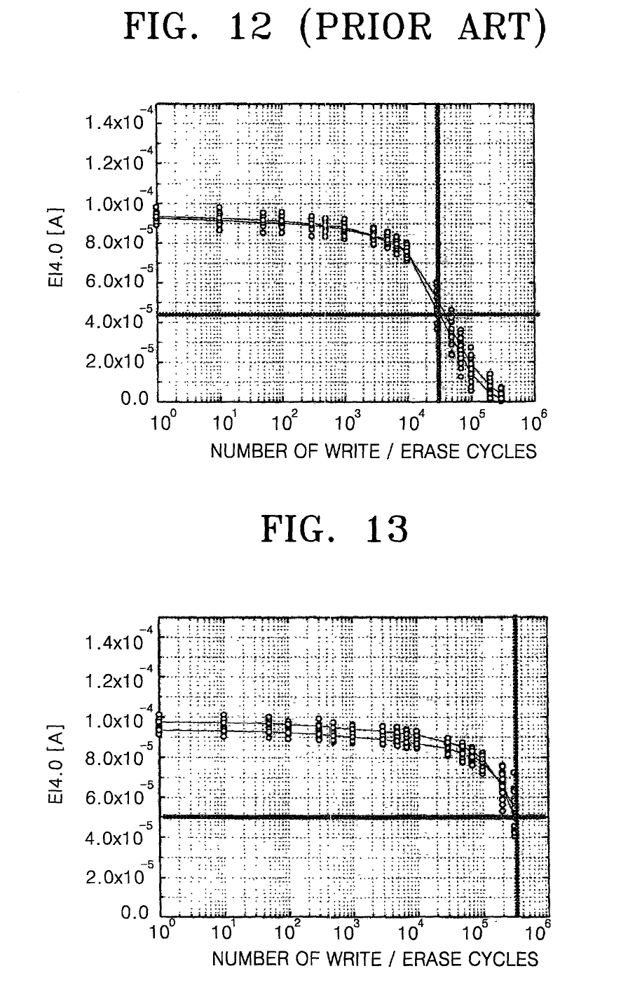

FIG. 11 illustrates bias applying conditions in erase/write operations for the cell array structure of FIG. 6 together with the detrap bias conditions shown in FIG. 11 for the stack gate flash memory in FIG. 10. Vₚₚ1 and Vₚₚ2 in FIG. 11 denote different voltages applied to a word line and a bit line, respectively, during a write step. FIG. 12 illustrates a drain current change characteristic under the bias conditions shown in FIG. 11, when erase/write operations are repeated without a detrap step according to the conventional method. FIG. 13 illustrates a drain current characteristic under the bias conditions shown in FIG. 7, when erase/write/detrap steps are repeated according to the present invention. Through comparison of the figures, it can be found that the programming method including a detrapping process according to an embodiment of the present invention reduces degradation of a memory cell.

Unlike the illustrated embodiments, bias conditions in which a predetermined potential is applied to the source 11 and drain 12 in a detrapping process may be applicable. Alternatively, bias conditions in which a predetermined bias voltage is applied during a detrapping process to at least two regions selected from the substrate 10, source 11, and drain 12 may be applicable.

In the case in which a detrapping process is added between erase and write steps, the bias conditions in a detrap process following a write step can be applied in the same manner.

According to the flash memory programming method of an embodiment of the present invention, a detrapping process is performed for removing electrons trapped in a region other than a floating gate, during an erase step for erasing data recorded in a memory cell and during a write step for recording data. The programming method according to an embodiment of the present invention can suppress degradation caused by repetition of erase/write operations by performing the detrapping process after an erase operation or write operation. In one of the embodiments of the present invention, the detrapping process is performed after a targeted number of write or erase operations instead of after each write or erase operation.

While the present invention has been described in terms of preferred embodiments, those of ordinary skill in the art will recognize that various modifications may be made to the invention without departing from the spirit and scope thereof.

What is claimed is:

1. A method of programming a flash memory module in which a plurality of flash memory cells are arrayed in a substrate; each memory cell having a source, a drain, a floating gate, and a control gate which are separated from one another on the substrate; an insulating layer formed on the substrate between the source and drain, and also separating the source/drain from the floating gate; the programming method comprising:
(a) performing a write operation by applying a predetermined bias condition that corresponds to data to be written to the flash memory cell; and
(b) performing a detrapping process by applying a predetermined bias condition to remove electrons trapped in the insulating layer excluding the floating gate during the write operation, following the write operation.

2. The method of claim 1, wherein the flash memory cell is a split gate type memory cell.

3. The method of claim 2, wherein, in (b), a predetermined bias voltage is applied to the source in such a way that the electric potential of the source is maintained higher than the electric potential of the floating gate.

4. The method of claim 2, wherein, in (b), a predetermined bias voltage is applied to the substrate in such a way that the electric potential of the substrate is maintained higher than the electric potential of the floating gate.

5. The method of claim 2, wherein, in (b), a predetermined bias voltage is applied to the drain in such a way that the electric potential of the drain is maintained higher than the electric potential of the floating gate.

6. The method of claim 1, wherein the flash memory cell is a stack gate type memory cell.

7. The method of claim 6, wherein, in (b), a predetermined bias voltage is applied to the source in such a way that the electric potential of the source is maintained higher than the electric potential of the floating gate.

8. The method of claim 6, wherein, in (b), a predetermined bias voltage is applied to the substrate in such a way that the electric potential of the substrate is maintained higher than the electric potential of the floating gate.

9. The method of claim 6, wherein, in (b), a predetermined bias voltage is applied to the drain in such a way that the electric potential of the drain is maintained higher than the electric potential of the floating gate.

10. The method of claim 1, wherein a predetermined number of flash memory cells are coupled on a block-by-block basis so that the memory cells may share the control gate and source,
wherein the write operation is performed on the flash memory cells within the block on a bit-by-bit basis at predetermined intervals, and
wherein the detrapping process is performed on all the flash memory cells within the block between each interval of the write operation which is made on a bit-by-bit basis.

11. The method of claim 1, wherein a predetermined number of flash memory cells are coupled on a block-by-block basis so that the memory cells may share the control gate and the source,
wherein the write operation is performed on the flash memory cells within the block on a byte-by-byte basis at predetermined intervals, and
wherein the detrapping process is performed on all the flash memory cells within the block between each interval of the write operation which is made on a byte-by-byte basis.

12. The method of claim 1, wherein a predetermined number of flash memory cells are coupled on a block-by-block basis so that the memory cells may share the control gate and the source, and
wherein the detrapping process is performed on the block whenever the write operation for the block is completed.

13. The method of claim 1, wherein a predetermined number of flash memory cells are coupled on a block-by-block basis so that the memory cells may share the control gate and the source with each other, and
wherein the detrapping process is intermittently performed on the block whenever a targeted number of the write operations for the block are performed, the targeted number of times being set to two times or more.

14. A method of programming a flash memory module in which a plurality of flash memory cells are arrayed in a substrate; each memory cell having a source, a drain, a floating gate, and a control gate which are separated from one another on the substrate; an insulating layer formed on the substrate between the source and drain, and also separating the source/drain from the floating gate; the programming method comprising:
(a) performing an erase operation by applying a predetermined bias condition established for erasing data written to the flash memory cell; and
(b) performing a detrapping process by applying a predetermined bias condition established for removing electrons trapped in the insulating layer excluding the floating gate, following the erase operation.

15. The method of claim 14, wherein the flash memory cell is a split gate type memory cell.

16. The method of claim 15, wherein, in (b), a predetermined bias voltage is applied to the source in such a way that the electric potential of the source is maintained higher than the electric potential of the floating gate.

17. The method of claim 15, wherein, in (b), a predetermined bias voltage is applied to the substrate in such a way that the electric potential of the substrate is maintained higher than the electric potential of the floating gate.

18. The method of claim 15, wherein, in (b), a predetermined bias voltage is applied to the drain in such a way that the electric potential of the drain is maintained higher than the electric potential of the floating gate.

19. The method of claim 15, wherein the flash memory cell is a stack gate type memory cell.

20. The method of claim 19, wherein, in (b), a predetermined bias voltage is applied to the source in such a way that the electric potential of the source is maintained higher than the electric potential of the floating gate.

21. The method of claim 19, wherein, in (b), a predetermined bias voltage is applied to the substrate in such a way that the electric potential of the substrate is maintained higher than the electric potential of the floating gate.

22. The method of claim 19, wherein, in (b), a predetermined bias voltage is applied to the drain in such a way that the electric potential of the drain is maintained higher than the electric potential of the floating gate.

23. The method of claim 2, wherein, in (b), predetermined bias voltages are applied to the source, drain and substrate regions in such a way that the electric potential of at least two regions among the source, drain and substrate regions are maintained higher than the electric potential of the floating gate.

24. The method of claim 6, wherein, in (b), predetermined bias voltages are applied to the source, drain and substrate regions in such a way that the electric potential of at least two regions among the source, drain and substrate regions are maintained higher than the electric potential of the floating gate.

25. The method of claim 15, wherein, in (b), predetermined bias voltages are applied to the source, drain and substrate regions in such a way that the electric potential of at least two regions among the source, drain and substrate are maintained higher than the electric potential of the floating gate.

26. The method of claim 19, wherein, in (b), predetermined bias voltages are applied to the source, drain and substrate regions in such a way that the electric potential of at least two regions among the source, drain and substrate regions are maintained higher than the electric potential of the floating gate.
